(19) United States
(12) Patent Application Publication
(10) Pub. No.: US 2013/0333618 A1
(43) Pub. Date: Dec. 19, 2013

(54) HALL EFFECT PLASMA SOURCE

(71) Applicant: Applied Materials, Inc., Santa Clara, CA (US)

(72) Inventor: Michael S. COX, Gilroy, CA (US)

(73) Assignee: Applied Materials, Inc., Santa Clara, CA (US)

(21) Appl. No.: 13/916,087

(22) Filed: Jun. 12, 2013

Related U.S. Application Data
(60) Provisional application No. 61/661,313, filed on Jun. 18, 2012.

(51) Int. Cl. C23C 16/52

(52) U.S. Cl. CPC C23C 16/52
USPC 118/723 FI

(57) ABSTRACT

The present invention generally relates to an apparatus for treating a substrate. The apparatus utilizes two plasma sources that operate in different phases (i.e., one positive phase while the other negative phase). By alternating phases, the current density is alternated between the sources such that one source can generate ions while the other source can generate electrons. Therefore, each adjacent source acts as the cathode in opposite to the anode of the adjacent source. By having adjacent sources having alternating phases, uniform deposition occurs.

### CROSS-REFERENCE TO RELATED APPLICATIONS

This application claims benefit of U.S. Provisional Patent Application Ser. No. 61/661,313 (APPM/16602L), filed Jun. 18, 2012, which is herein incorporated by reference.

### BACKGROUND OF THE INVENTION

1. Field of the Invention

Embodiments of the present invention generally relate to a plasma source for depositing material onto substrates.

2. Description of the Related Art

Plasma enhanced chemical vapor deposition (PECVD) is a deposition method that is used for depositing material onto a substrate. In a PECVD method, precursors are delivered to a processing chamber and ignited into a plasma. The precursors react to deposit a reaction product onto the substrate. PECVD is used in many industries, such as solar cell manufacture, semiconductor processing, and flat panel display manufacture to name a few.

One of the challenges in PECVD processing is forming a uniform plasma. When the plasma is not uniform, then the deposited layer may not be uniform either in terms of the film thickness and other film properties. When the deposited material is non-uniform, a reliable product cannot be produced. Because the deposited material is non-uniform, repeatability of the results is unlikely. While some non-uniformity would likely occur in the next processed substrate, the non-uniformity may be different. Thus, substrate to substrate repeatability is highly unlikely which leads potential reliability issues for the ultimate product in which the substrate will result.

Therefore, there is a need in the art for a plasma apparatus that can permit uniform processing of a substrate.

### SUMMARY OF THE INVENTION

The present invention generally relates to an apparatus for treating a substrate. The apparatus utilizes two plasma sources that operate in different phases (i.e., one positive phase while the other negative phase). By alternating phases, the current density is alternated between the sources such that one source can generate ions while the other source can generate electrons. Therefore, each adjacent source acts as the cathode in opposite to the anode of the adjacent source. By having adjacent sources having alternating phases, uniform deposition occurs.

In one embodiment, a plasma enhanced chemical vapor deposition apparatus is disclosed. The apparatus comprises a chamber body, a first source disposed in the chamber body and a second source disposed in the chamber body and surrounding the first source. The first source comprises a first outer shell, a first electrode disposed in the first outer shell shaped to form a first cavity portion, a first magnetic shunt coupled with the first electrode, a first plate coupled with the first outer shell, and a first magnet disposed adjacent the first plate and adjacent an end of the first cavity portion.

In another embodiment, a plasma enhanced chemical vapor deposition apparatus is disclosed. The apparatus comprises a chamber body, a first source disposed in the chamber body and a second source disposed in the chamber body and surrounded by the first source. The first source comprises a first outer shell, a first electrode disposed in the first outer shell shaped to form a first cavity portion, a first magnetic shunt coupled with the first electrode, a first plate coupled with the first outer shell, and a first magnet disposed adjacent the first plate and adjacent an end of the first cavity portion.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A and 1B are schematic cross-sectional and bottom views of two sources according to one embodiment.

FIGS. 2A and 2B are schematic cross-sectional and bottom views of two sources according to another embodiment.

FIGS. 3A and 3B are schematic cross-sectional and bottom views of two sources according to another embodiment.

FIGS. 4A and 4B are schematic cross-sectional and bottom views of two sources according to another embodiment.

FIG. 5 is a schematic illustration of a processing chamber containing plasma sources according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present invention generally relates to an apparatus for treating a substrate. The apparatus utilizes two plasma sources that operate in different phases (i.e., one positive phase while the other negative phase). By alternating phases, the current density is alternated between the sources such that one source can generate ions while the other source can generate electrons. Therefore, each adjacent source acts as the cathode in opposite to the anode of the adjacent source. By having adjacent sources having alternating phases, uniform deposition occurs.

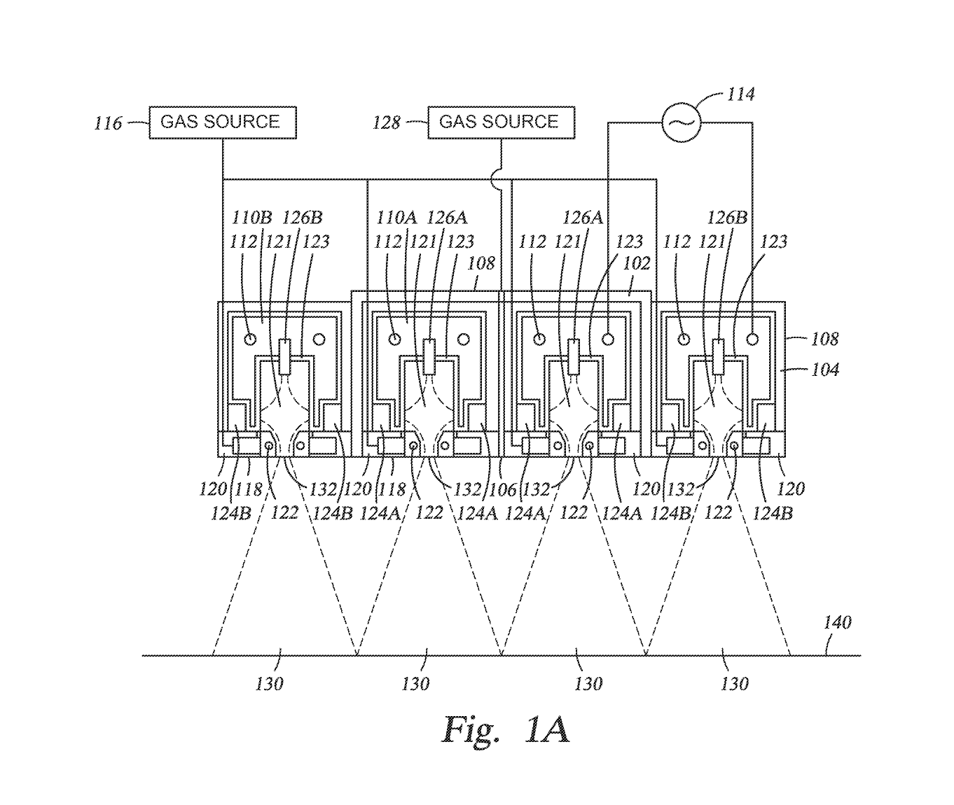

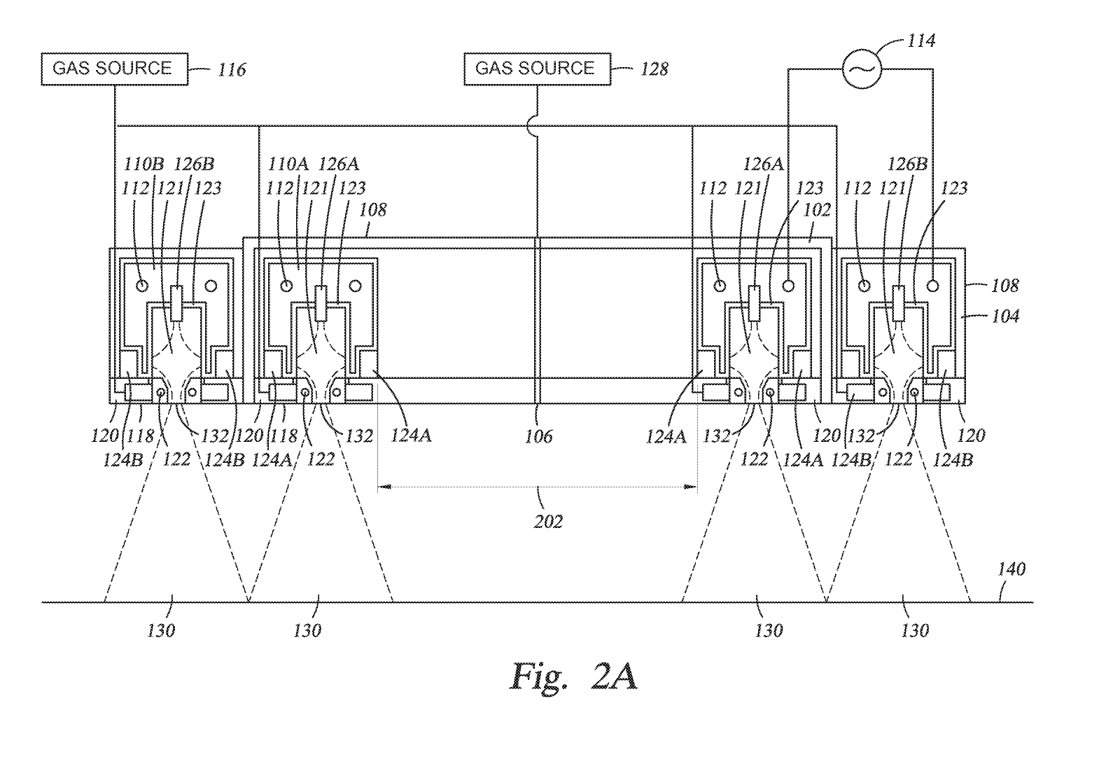

FIGS. 1A and 1B are schematic cross-sectional and bottom views of two sources 102, 104 that are utilized for PECVD deposition according to one embodiment. As shown in FIG. 1B, the first source 102 is surrounded by the second source 104. A nozzle 106 is shown for introducing processing gas into the chamber. A gas source 128 is present to deliver the gas through nozzle 106. Each source 102, 104 includes an outer shell 108 that encloses an electrode 110A, 1108. Each electrode 110A, 1108 has cooling passages 112 formed therein. The electrodes 110A, 1108 are coupled to a common power supply 114 and, in operation, driven in opposite phases as will be discussed below. In one embodiment, the power supply 114 is an AC power supply.

Gas is introduced also introduced to the sources 102, 104 from a gas source 116 through a gas manifold 118 formed in plate 120. The plate 120 is cooled by cooling fluid that flows through cooling channels 122. The plate 120 is coupled to the outer shell 108 by well known fastening mechanisms (not shown) such as screws. The plate 120 has an opening therethrough that forms a nozzle 132.

Each source has a cavity portion 121 that is bound by a liner 123 that covers the electrodes 110A, 1108. The electrodes 110A, 1108 are shaped to form the cavity portion. The liner 123 facilitates heat transfer in the sources 102, 104. Magnets 124A, 124B are disposed adjacent an end of the cavity portion 121 and adjacent the plate 120. The magnets 124A, 124B may comprise permanent magnets or, alternatively, magnetrons. Magnets 124A, 124B are opposite polarity. Additionally, magnet shunts 126A, 126B are present within the cavity portion 121 and coupled to the electrodes 110A, 1108. The magnet shunts 126A, 126B are opposite polarity to the respective magnetrons 124A, 124B. Collectively, the magnets 124A, 124B and the shunts 126A, 126B shape a magnetic field that affects the deposition.

The two electrodes 110A, 1108 are connected on opposite sides of the AC power supply 114. In one embodiment, power supply 114 is an alternating current power supply with a frequency range between 20 kHz to 500 kHz. Reactive and/or inert gases are introduced into cavity portions 121 via gas manifolds 118. Simultaneously, a second gas is introduced through the nozzle 106. The electrodes 110A, 1108 each alternate as the cathode and the anode during processing. While one electrode 110A, 1108 is a cathode, the other electrode 110A, 1108 is the anode for the circuit. The two sources 110A, 110B by alternating as anode and cathode, prevent buildup of material on the liner 123 because any buildup is continuously removed.

The sources 102, 104 generate an ion beam for depositing material onto a substrate. While operating as an anode, all electrons from a source 102, 104 must flow to the source 102, 104 to return to the power supply 114. To reach the internal electrode 110A, 110B, the electrons must enter cavity portion 121 through nozzle 132. As electrons move toward the nozzle 132, the electrons are impeded by a positively charged electric field emanating through nozzle 132. The positively charged electric field is created by the strong magnetic field in nozzle 132 extending out to a weaker field region closer to a substrate. As electron current flow is impeded across the positively charged electric field, a voltage drop is produced

As electrons are being impeded from flowing into cavity portion 121, gas atoms are flowing out of cavity portion 121 through nozzle 132. These neutral atoms collide with electrons such that ions are formed. The ions then are accelerated out of source 102, 104 toward substrate. This overall effect is similar to ion sources employing the “End Hall” effect with an axial electron mirror confinement. In operation, a dense, linear beam of ions flows out of the sources 102, 104 toward substrate on each half cycle. At the same time electrons flowing out of the cathode source 102, 104 neutralize the generated ion beam. The result is an ideal neutralized, uniform, dense beam directed at the substrate.

In the embodiments shown in FIGS. 1A and 1B, the first source 102 is surrounded by the second source 104. Thus, when the first source 102 is operating as the cathode, the anode surrounds the cathode. Similarly, when the second source 104 operates as the cathode, the anode is surrounded by the cathode. The quick cycling between cathode and anode causes the electrons to continuously shift between adjacent sources 102, 104.

In the embodiment of FIGS. 1A and 1B, the sources 102, 104 are circular in shape to accommodate processing a circular substrate having approximately the same diameter as the second source 104. As shown in FIG. 1A, the plasma plume 130 from each source collectively spans the entire diameter of the second source 104 and thus, is sufficiently large to accommodate processing the entire substrate 140. The substrate that is processed may be a static substrate or a dynamic substrate.

In operation, the two sources 102, 104 operate collectively to deposit a uniform film on a substrate 140. A processing gas is introduced through nozzle 106 from gas source 128. The processing gas is typically the precursor utilized to deposit the film. Simultaneously, a reactive gas and/or inert gas is introduced through manifold 118 in top place 120 from gas source 116. As the gas is introduced through the manifold 118 and nozzle 106, power is applied to the electrodes 110A, 110B from power source 114. The electrodes 110A, 110B are driven in opposite phases such that one electrode 110A, 110B operates as an anode while the other electrode 110A, 110B operates as a cathode. The electrical bias to the electrodes 110A, 110B causes electrons to be generated by the source 102, 104 operating as a cathode that collect near the nozzle 106 of the source 102, 104 operating as an anode 102, 104. The electrons cannot penetrate into the cavity portion 121 of the anode source 102, 104 due to the magnetic field generated by the magnets 124A, 124B and shunt 126A, 126B. Simultaneously, gas atoms introduced from the manifold 118 are flowing out of the nozzle 132. The gas atoms collide with the electrons and generate ions. The ions are then accelerated towards the substrate due to the potential difference between the electric field created by the electrons collected near the nozzle 132 and the bias applied to the electrode 110A, 110B. The ions generate a plasma plume 130 that permits even deposition on the substrate.

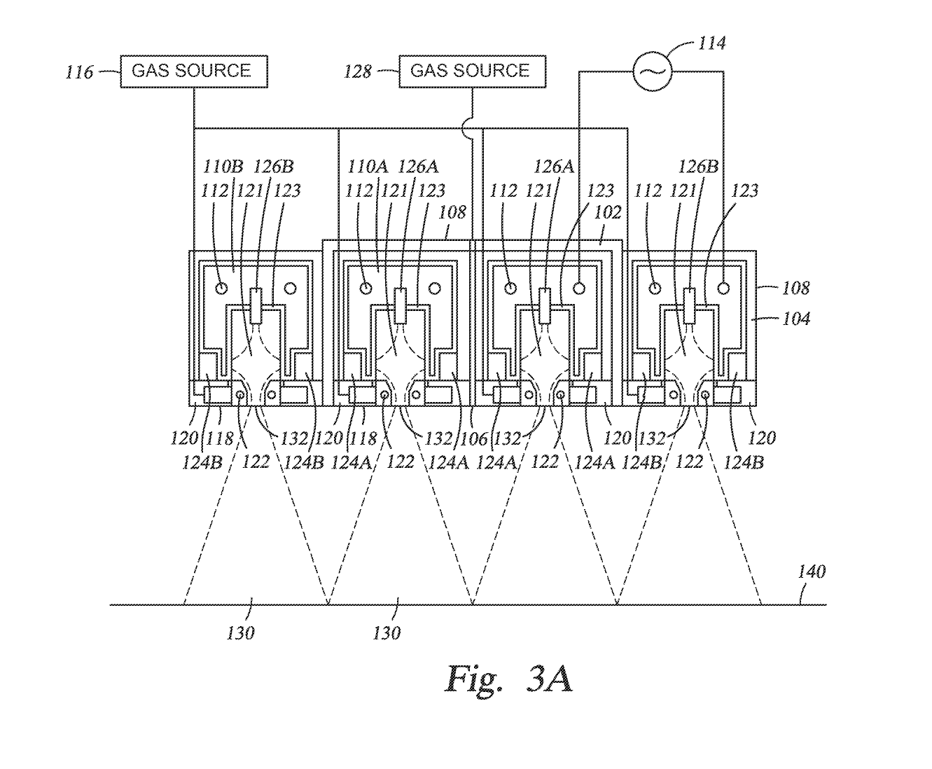

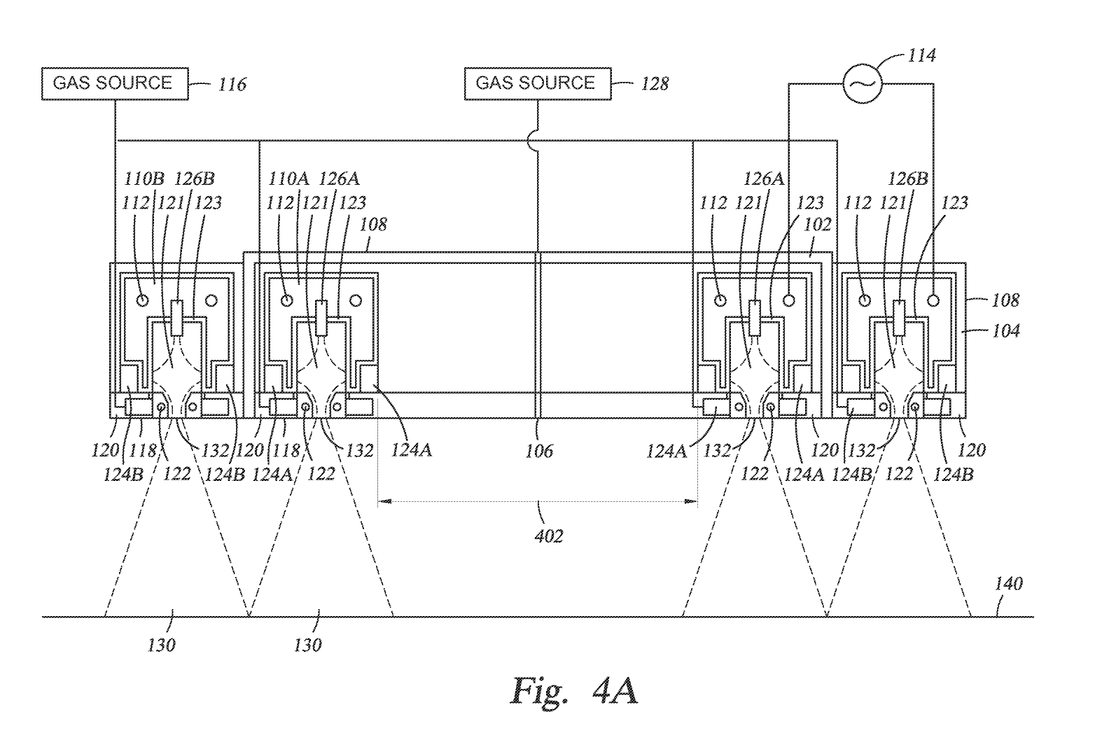

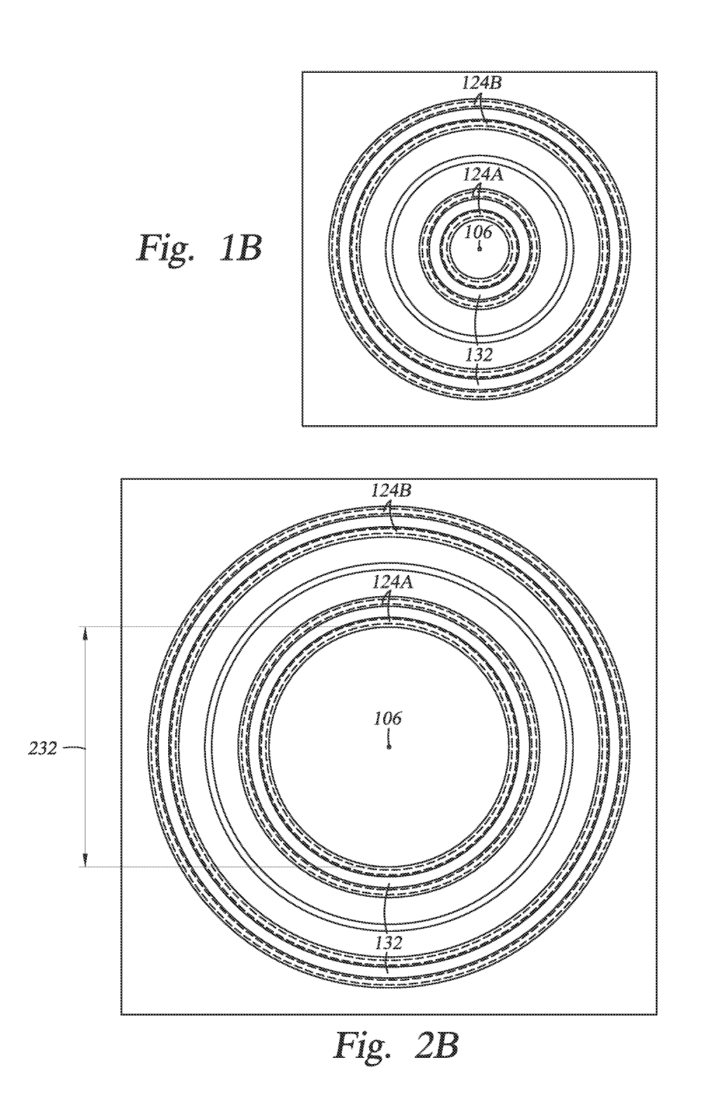

The geometrical arrangement of the sources 102, 104 can be altered as necessary. For example, FIGS. 2A and 2B are schematic cross-sectional and bottom views of two sources according to another embodiment. In the embodiment shown in FIGS. 2A and 2B, the sources 102, 104 are designed such that the inner diameter 202 of the first source 102 is equal to or larger than the diameter of the substrate to be processed. Such an arrangement can be beneficial for atomic layer deposition (ALD) because the plasma plume 130 would not directly contact the substrate. Alternatively, such an arrangement can permit edge processing of the substrate whereby the middle area of the substrate remains unprocessed.

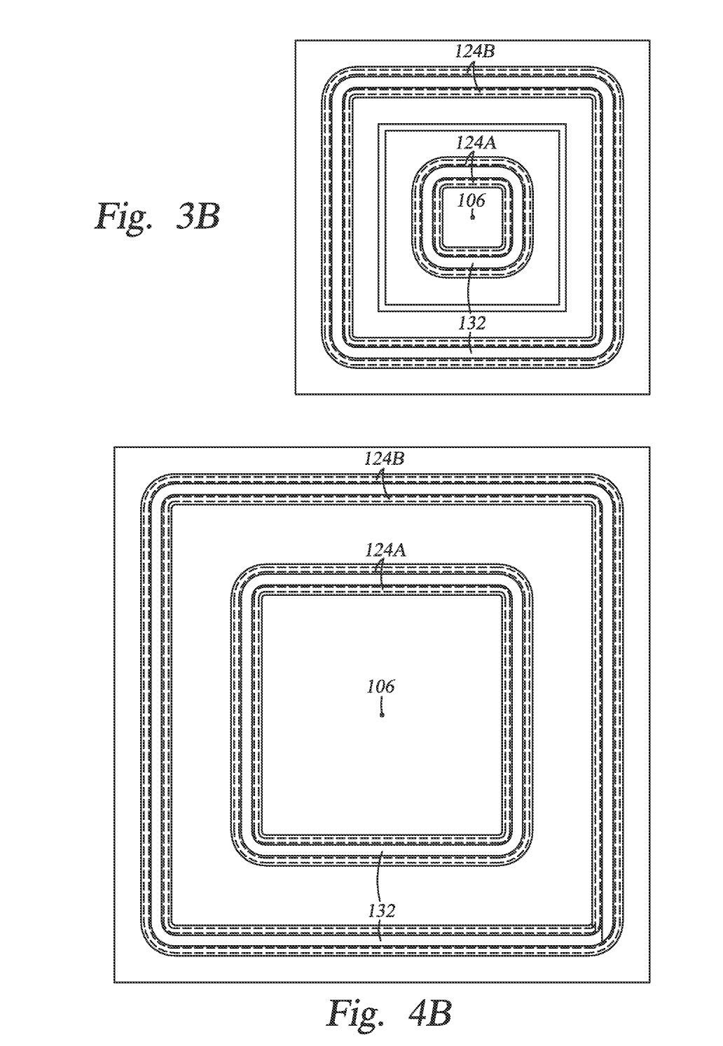

FIGS. 3A and 3B are schematic cross-sectional and bottom views of two sources according to another embodiment. In FIGS. 3A and 3B, the sources 102, 104 are designed to accommodate processing a rectangular shaped substrate. Thus, as shown in FIG. 3B, the sources have rectangular shaped nozzles 132.

FIGS. 4A and 4B are schematic cross-sectional and bottom views of two sources according to another embodiment. In FIGS. 4A and 4B, similar to FIGS. 2A and 2B, the sources 102, 104 are designed such that the inner diameter 402 of the first source 102 is equal to or greater than the diameter of the substrate to be processed. However, similar to FIGS. 3A and 3B, the sources 102, 104 are arranged to accommodate processing a rectangular shaped substrate. Thus, the nozzles 132 all have a rectangular shape.

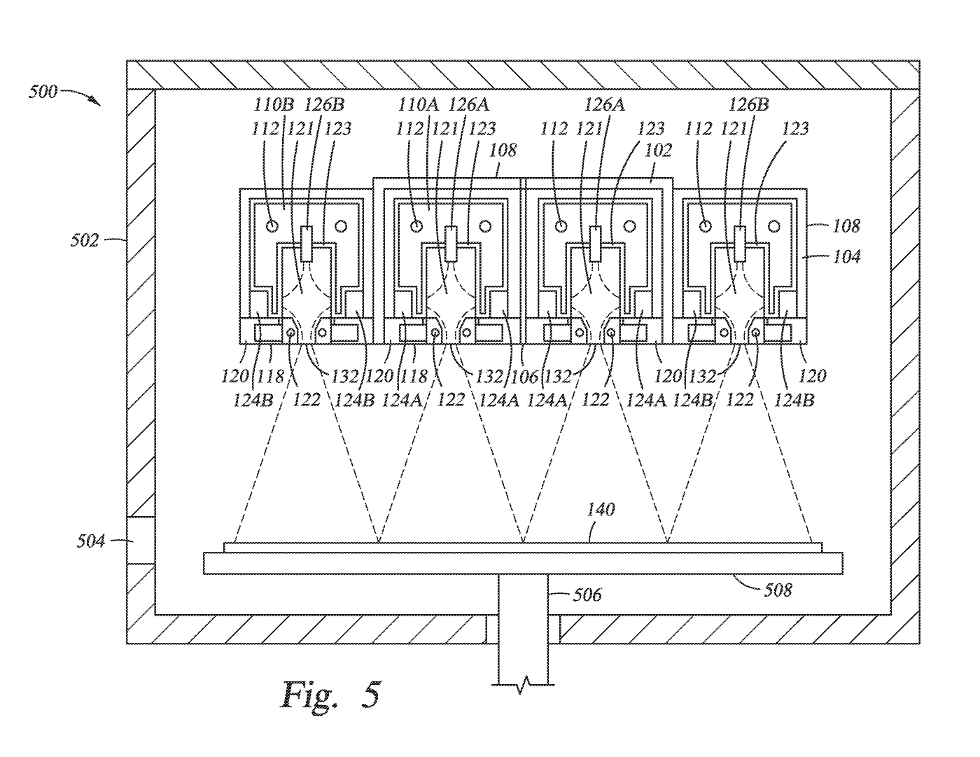

FIG. 5 is a schematic illustration of a processing chamber 500 containing plasma sources according to one embodiment. The processing chamber 500 includes a chamber body having walls 502 and a slit valve opening 504 therethrough to permit entry and exit of the substrate 140. The substrate 140, once inserted into the processing chamber 500 is disposed on a susceptor 508 that is coupled to a stem 506. The stem 506 is movable to adjust the distance between the substrate 140 and the sources 102, 104. It is to be understood that while the processing chamber 500 shows the cross-sectional view of sources 102, 104 from the arrangements shown in FIGS. 1A and 3A, the arrangements shown in FIGS. 2A and 4A may be utilized in a chamber body similar to FIG. 5A as well.

While the foregoing is directed to embodiments of the present invention, other and further embodiments of the invention may be devised without departing from the basic scope thereof, and the scope thereof is determined by the claims that follow.

1. A plasma enhanced chemical vapor deposition apparatus, comprising:
a chamber body;
a first source disposed in the chamber body, the first source comprising:
a first outer shell;
a first electrode disposed in the first outer shell shaped to form a first cavity portion;
a first magnetic shunt coupled with the first electrode;
a first plate coupled with the first outer shell;
a first magnet disposed adjacent the first plate and adjacent an end of the first cavity portion; and
a second source disposed in the chamber body and surrounding the first source.

2. The apparatus of claim 1, wherein the second source comprises:
a second outer shell;
a second electrode disposed in the second outer shell shaped to form a second cavity portion;
a second magnetic shunt coupled with the second electrode;
a second plate coupled with the second outer shell; and
a second magnet disposed adjacent the second plate and adjacent an end of the second cavity portion.

3. The apparatus of claim 2, wherein the both the first plate and the second plate each comprise a gas manifold.

4. The apparatus of claim 1, wherein the first source and the second source are circular.

5. The apparatus of claim 4, wherein the first source and the second source each have an inner diameter that is greater than or equal to a diameter of a substrate to be processed.

6. The apparatus of claim 1, wherein the first source and the second source are rectangular.

7. The apparatus of claim 6, wherein the first source and the second source are sized to surround a substrate to be processed.

8. The apparatus of claim 1, further comprising a gas inlet surrounded by the first and second sources.

9. The apparatus of claim 1, further comprising an AC power source coupled to both the first source and the second source.

10. The apparatus of claim 1, wherein the first plate further comprises a gas manifold.

11. A plasma enhanced chemical vapor deposition apparatus, comprising:
a chamber body;
a first source disposed in the chamber body, the first source comprising:
a first outer shell;
a first electrode disposed in the first outer shell shaped to form a first cavity portion;
a first magnetic shunt coupled with the first electrode;
a first plate coupled with the first outer shell;
a first magnet disposed adjacent the first plate and adjacent an end of the first cavity portion; and
a second source disposed in the chamber body and surrounded by the first source.

12. The apparatus of claim 11, wherein the second source comprises:
a second outer shell;
a second electrode disposed in the second outer shell shaped to form a second cavity portion;
a second magnetic shunt coupled with the second electrode;
a second plate coupled with the second outer shell; and
a second magnet disposed adjacent the second plate and adjacent an end of the second cavity portion.

13. The apparatus of claim 12, wherein the both the first plate and the second plate each comprise a gas manifold.

14. The apparatus of claim 11, wherein the first source and the second source are circular.

15. The apparatus of claim 14, wherein the first source and the second source each have an inner diameter that is greater than or equal to a diameter of a substrate to be processed.

16. The apparatus of claim 11, wherein the first source and the second source are rectangular.

17. The apparatus of claim 16, wherein the first source and the second source are sized to surround a substrate to be processed.

18. The apparatus of claim 11, further comprising a gas inlet surrounded by the first and second sources.

19. The apparatus of claim 11, further comprising an AC power source coupled to both the first source and the second source.

20. The apparatus of claim 11, wherein the first plate further comprises a gas manifold.
